(19) United States
(12) Patent Application Publication
(10) Pub. No.: US 2024/0039512 A1
(43) Pub. Date: Feb. 1, 2024

(54) Twin Double-Mode Surface-Acoustic-Wave (DMS) Filters with Opposite Polarities and a Geometric Offset

(71) Applicant: RF360 Singapore Pte. Ltd., Singapore (SG)

(72) Inventors: Aymen Oueslati, Biot (FR); Jacques-Antoine Damy, Nice (FR)

(21) Appl. No.: 17/815,538

(22) Filed: Jul. 27, 2022

(51) Int. Cl. H03H 9/145; H03H 9/64; H03H 3/10

(52) U.S. Cl. CPC H03H 9/14544; H03H 9/6406; H03H 3/10

(57) ABSTRACT

An apparatus for filtering is disclosed that implements twin double-mode surface-acoustic-wave filters with opposite polarities and a geometric offset. The apparatus includes a first double-mode surface-acoustic-wave structure comprising an electrode structure having a first quantity of fingers and a first pitch. The first double-mode surface-acoustic-wave structure has a first polarity. The apparatus also includes a second double-mode surface-acoustic-wave structure coupled to the first double-mode surface-acoustic-wave structure with a second polarity that is opposite the first polarity. The second double-mode surface-acoustic-wave structure comprises an electrode structure having a second quantity of fingers and a second pitch. The second quantity of fingers is equal to the first quantity of fingers. The second pitch differs from the first pitch by a pitch offset.

### TECHNICAL FIELD

This disclosure relates generally to wireless transceivers and other components that employ filters and, more specifically, to implementing two double-mode surface-acoustic-wave (DMS) filters that are coupled together with opposite polarities and have at least one geometric offset.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for radio-frequency applications, including those that utilize frequencies above 100 megahertz (MHz).

### SUMMARY

An apparatus is disclosed that implements twin double-mode surface-acoustic-wave filters with opposite polarities and a geometric offset. The twin double-mode surface-acoustic-wave filters represent two double-mode surface-acoustic-wave filters with similar physical structures. The two double-mode surface-acoustic-wave filters are coupled together with opposite polarities to cause a phase difference between the double-mode surface-acoustic-wave filters to be approximately zero degrees within a passband and approximately 180 degrees outside of the passband. The physical structures of the two double-mode surface-acoustic-wave filters can be approximately symmetrical to each other and are related together by at least one geometric offset. The geometric offset can be optimized to enable the twin double-mode surface-acoustic-wave filters to attenuate out-of-band frequencies by a target amount. By using two double-mode surface-acoustic-wave filters, the twin double-mode surface-acoustic-wave filters can have a more compact design than other types of filters while achieving similar or better out-of-band frequency suppression performance.

In an example aspect, an apparatus for filtering is disclosed. The apparatus includes a first double-mode surface-acoustic-wave structure comprising an electrode structure having a first quantity of fingers and a first pitch. The first double-mode surface-acoustic-wave structure has a first polarity. The apparatus also includes a second double-mode surface-acoustic-wave structure coupled to the first double-mode surface-acoustic-wave structure with a second polarity that is opposite the first polarity. The second double-mode surface-acoustic-wave structure comprises an electrode structure having a second quantity of fingers and a second pitch. The second quantity of fingers is equal to the first quantity of fingers. The second pitch differs from the first pitch by a pitch offset.

In an example aspect, an apparatus for filtering is disclosed. The apparatus includes a first double-mode surface-acoustic-wave structure comprising an electrode structure having a first quantity of fingers and a first chirp. The first double-mode surface-acoustic-wave structure has a first polarity. The apparatus also includes a second double-mode surface-acoustic-wave structure coupled to the first double-mode surface-acoustic-wave structure with a second polarity that is opposite the first polarity. The second double-mode surface-acoustic-wave structure comprises an electrode structure having a second quantity of fingers and a second chirp. The second quantity of fingers is equal to the first quantity of fingers. The second chirp differs from the first chirp by a chirp offset.

In an example aspect, a method for manufacturing twin double-mode surface-acoustic-wave filters with opposite polarities and a geometric offset is disclosed. The method includes providing a first double-mode surface-acoustic-wave filter having an electrode structure with a first quantity of fingers. The method also includes providing a second double-mode surface-acoustic-wave filter having an electrode structure with a second quantity of fingers that is equal to the first quantity of fingers. The electrode structure of the second double-mode surface-acoustic-wave filter is approximately symmetrical to the electrode structure of the first double-mode surface-acoustic-wave filter and related by a geometric offset. The method additionally includes coupling the second double-mode surface-acoustic-wave filter to the first double-mode surface-acoustic-wave filter with a polarity that is opposite a polarity of the first double-mode surface-acoustic-wave filter.

In an example aspect, an apparatus is disclosed. The apparatus includes two double-mode surface-acoustic-wave structures coupled together with opposite polarities. The two double-mode surface-acoustic-wave structures have physical structures that are approximately symmetrical to each other and are related by at least one geometric offset.

### BRIEF DESCRIPTION OF DRAWINGS

FIG. 1 illustrates an example operating environment for twin double-mode surface-acoustic-wave filters with opposite polarities and a geometric offset.

FIG. 2 illustrates an example wireless transceiver including twin double-mode surface-acoustic-wave filters with opposite polarities and a geometric offset.

FIG. 3 illustrates example components of a double-mode surface-acoustic-wave filter.

FIG. 4 illustrates an example implementation of a portion of a double-mode surface-acoustic-wave filter.

FIG. 5 illustrates an example electrode structure of a double-mode surface-acoustic-wave filter.

FIG. 6 illustrates example geometric properties of a double-mode surface-acoustic-wave filter.

FIG. 7-1 illustrates example twin double-mode surface-acoustic-wave filters with opposite polarities and a geometric offset.

FIG. 7-2 illustrates an example tuning circuit coupled between twin double-mode surface-acoustic-wave filters.

FIG. 8 illustrates an example frequency response of twin double-mode surface-acoustic-wave filters with opposite polarities and a geometric offset.

FIG. 9 is a flow diagram illustrating an example process for manufacturing twin double-mode surface-acoustic-wave filters with opposite polarities and a geometric offset.

### DETAILED DESCRIPTION

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electrical and acoustic waves.

The acoustic wave propagates across the piezoelectric material at a velocity having a magnitude that is significantly less than that of the propagation velocity of the electromagnetic wave. Generally, the magnitude of the propagation velocity of a wave is proportional to a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones.

It can be challenging, however, to design an acoustic filter that can provide sufficient out-of-band frequency suppression with a compact design. Some techniques use a double-mode surface-acoustic-wave (DMS) filter, which can have a smaller footprint compared to other types of acoustic filters. By itself, however, the double-mode surface-acoustic-wave filter might not be able to attenuate frequencies outside of a passband by a desired amount. As such, other acoustic resonators may be added, such as multiple surface-acoustic-wave filters arranged in a ladder-type structure. These additional filters can significantly increase an overall footprint of a wireless transceiver, which can make it challenging to integrate within space-constrained devices.

To address this challenge, example techniques for implementing twin double-mode surface-acoustic-wave filters with opposite polarities and a geometric offset are described. The twin double-mode surface-acoustic-wave filters represent two double-mode surface-acoustic-wave filters with similar physical structures, such as a similar quantity of fingers, a similar quantity of interdigital transducers, and/or a similar aperture length. The two double-mode surface-acoustic-wave filters are coupled together with opposite polarities. This causes a phase difference between the double-mode surface-acoustic-wave filters to be approximately zero degrees within a passband and approximately 180 degrees outside of the passband.

The physical structures of the two double-mode surface-acoustic-wave filters can be approximately symmetrical to each other and are related together by at least one geometric offset. Example geometric offsets include a pitch offset and a chirp offset. The geometric offset can be optimized to enable the twin double-mode surface-acoustic-wave filters to attenuate out-of-band frequencies by a target amount. By using two double-mode surface-acoustic-wave filters, the twin double-mode surface-acoustic-wave filters can have a more compact design than other types of filters while achieving similar or better out-of-band frequency suppression performance. In some situations, the twin double-mode surface-acoustic-wave filters can provide adequate out-of-band frequency suppression without the use of additional acoustic filters.

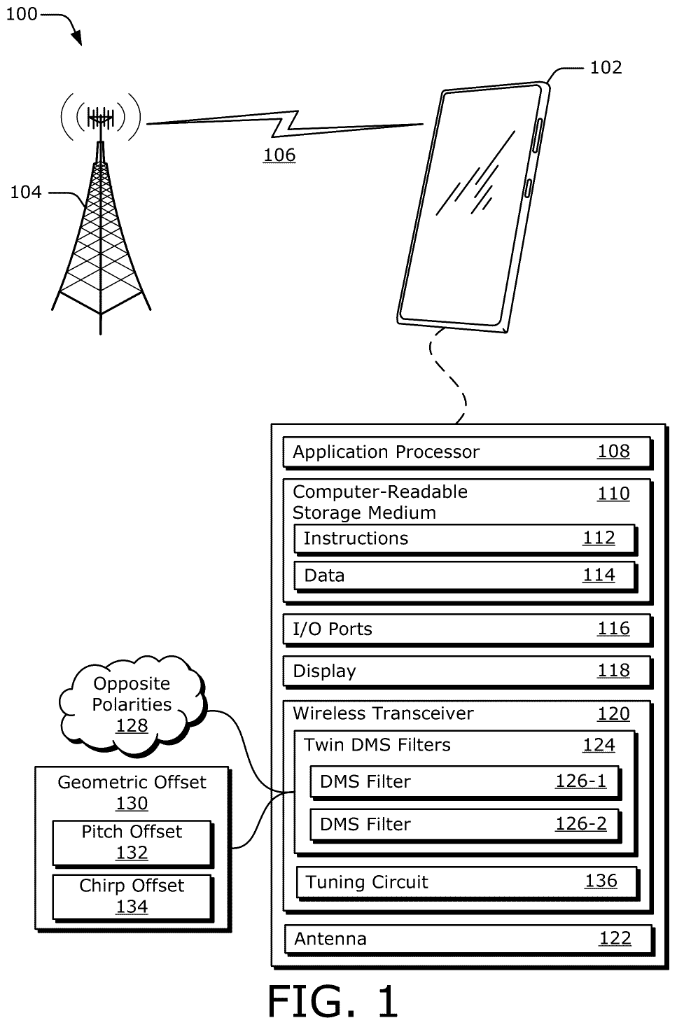

FIG. 1 illustrates an example environment 100 for operating twin double-mode surface-acoustic-wave filters with opposite polarities and a geometric offset. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one set of twin double-mode surface-acoustic-wave filters 124 (twin DMS filters 124) (or twin double-mode surface-acoustic-wave structures). The twin double-mode surface-acoustic-wave filters 124 include two double-mode surface-acoustic-wave filters 126-1 and 126-2 (or two double-mode surface-acoustic-wave structures). Each double-mode surface-acoustic-wave filter 126-1 and 126-2 can be implemented as, for example, a longitudinal-coupled double-mode surface-acoustic-wave (LDMS) filter. The twin double-mode surface-acoustic-wave filters 124 can be implemented using a thin-film surface-acoustic-wave (TFSAW) filter stack or a high-quality temperature-compensated surface-acoustic-wave (HQTC) filter stack.

The double-mode surface-acoustic-wave filters 126-1 and 126-2 are coupled together with opposite polarities 128. Also, the double-mode surface-acoustic-wave filters 126-1 and 126-2 have physical structures that are approximately the same. In some implementations, the physical structures of the double-mode surface-acoustic-wave filters 126-1 and 126-2 are substantially or approximately symmetrical to each other. For example, the double-mode surface-acoustic-wave filters 126-1 and 126-2 have the same quantity of fingers, the same quantity of interdigital transducers, approximately the same busbar lengths, and/or approximately the same aperture length. In general, the term “approximately” can mean that a length associated with the second double-mode surface-acoustic-wave filter 126-2 can be within +/−10% of the a corresponding length of the first double-mode surface-acoustic-wave filter 126-1 or less (e.g., within +/−5%, +/−3%, or +/−2% of the length of the first double-mode surface-acoustic-wave filter 126-1).

The physical structures of the twin double-mode surface-acoustic-wave filters 124 are related or linked together by at least one geometric offset 130. Example geometric offsets 130 include a pitch offset 132 and a chirp offset 134. The pitch offset 132 represents a difference in pitch between the double-mode surface-acoustic-wave filters 126-1 and 126-2. The chirp offset 134 represents a difference in a chirp between the double-mode surface-acoustic-wave filters 126-1 and 126-2.

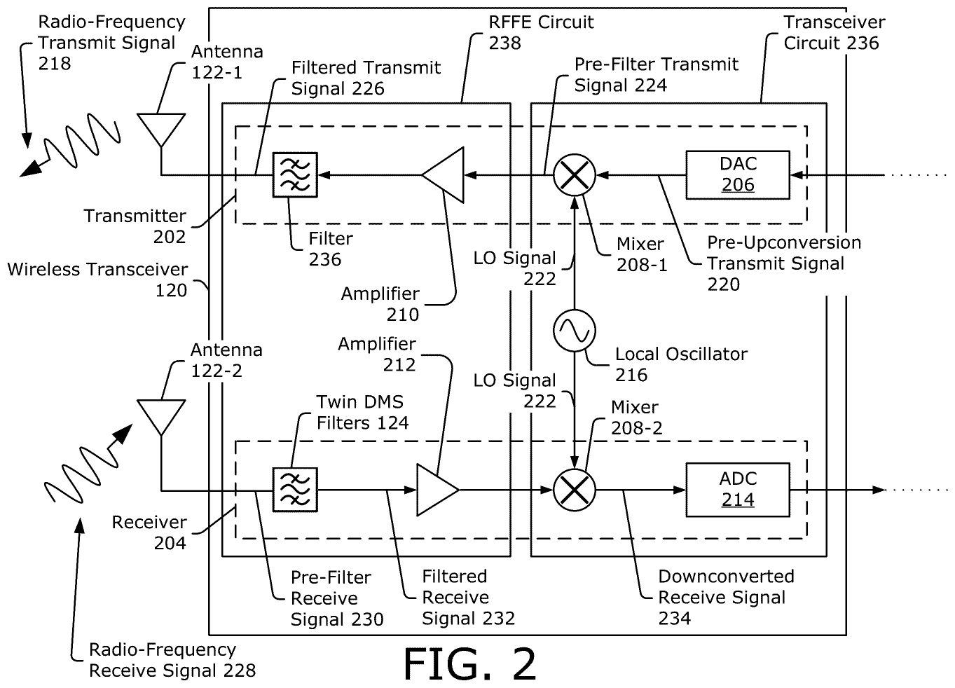

The wireless transceiver 120 can optionally include a tuning circuit 136, which is coupled between the first double-mode surface-acoustic-wave filter 126-1 and the second double-mode surface-acoustic-wave filter 126-2. The tuning circuit 136 can provide additional attenuation for out-of-band frequencies. The wireless transceiver 120 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one filter 236. The filter 236 can be implemented as an acoustic filter. The receiver 204 includes at least one set of twin double-mode surface-acoustic-wave filters 124, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the filter 236 of the transmitter 202, the twin double-mode surface-acoustic-wave filters 124 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an unconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the filter 236.

The filter 236 filters the amplified pre-filter transmit signal 224 to generate a filtered transmit signal 226. As part of the filtering process, the filter 236 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The twin double-mode surface-acoustic-wave filters 124 accept the received radio-frequency receive signal 228, which is represented by a pre-filter receive signal 230. The twin double-mode surface-acoustic-wave filters 124 filter any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which a set of twin double-mode surface-acoustic-wave filters 124 may be included. For example, the set of twin double-mode surface-acoustic-wave filters 124 can be integrated within duplexers or diplexers of the wireless transceiver 120. Also, some implementations of the wireless transceiver 120 can implement the filter 236 using another set of twin double-mode surface-acoustic-wave filters 124. Example implementations of the twin double-mode surface-acoustic-wave filters 124 are further described with respect to FIGS. 3 to 7-2.

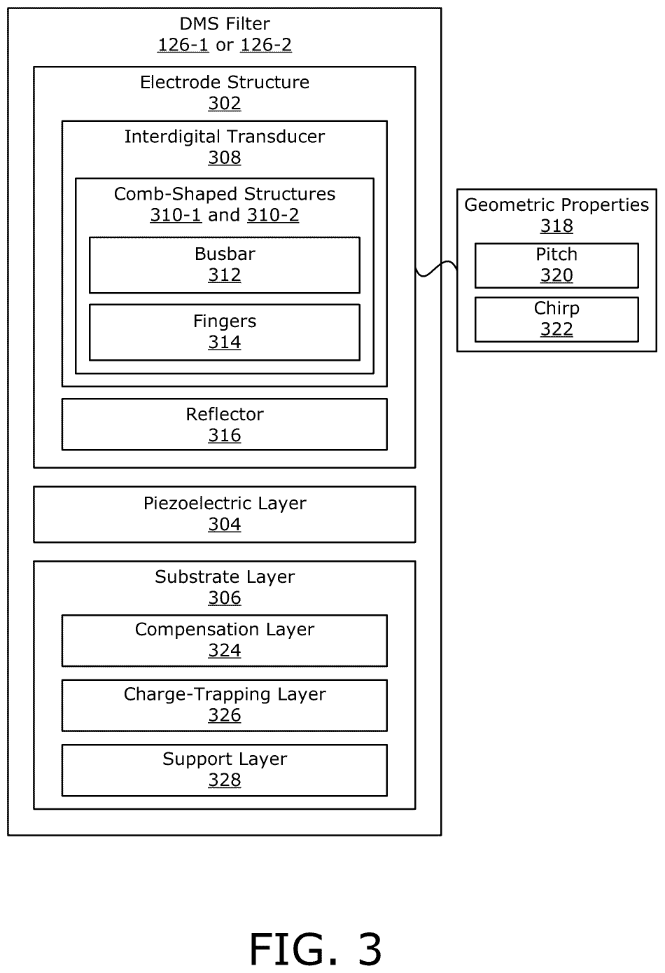

FIG. 3 illustrates example components of the double-mode surface-acoustic-wave filter 126-1 or 126-2. In the depicted configuration, the double-mode surface-acoustic-wave filter 126 includes an electrode structure 302, a piezoelectric layer 304, and at least one substrate layer 306. The electrode structure 302 comprises an electrically conductive material, such as metal, and can include one or more layers. The one or more layers can include one or more metal layers and can optionally include one or more adhesion layers. As an example, the metal layers can be composed of aluminium (Al), copper (Cu), silver (Ag), gold (Au), tungsten (W), platinum (Pt), or some combination or doped version thereof. The adhesion layers can be composed of chromium (Cr), titanium (Ti), molybdenum (Mo), or some combination thereof.

The electrode structure 302 can include three or more interdigital transducers 308. The interdigital transducers 308 convert an electrical signal into an acoustic wave and converts the acoustic wave into a filtered electrical signal. Each interdigital transducer 308 includes at least two comb-shaped structures 310-1 and 310-2. Each comb-shaped structure 310-1 and 310-2 includes a busbar 312 (e.g., a conductive segment or rail) and multiple fingers 314 (e.g., electrode fingers). The electrode structure 302 can also optionally include two or more reflectors 316. In an example implementation, the interdigital transducers 304 are arranged between two reflectors 316, which reflect the acoustic wave back towards the interdigital transducers 308.

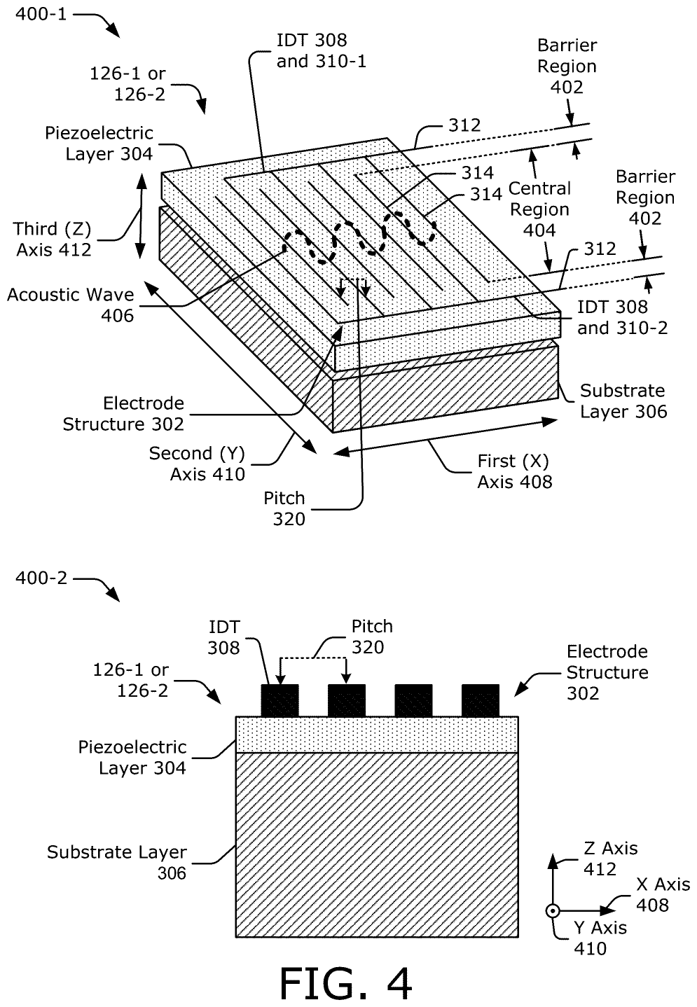

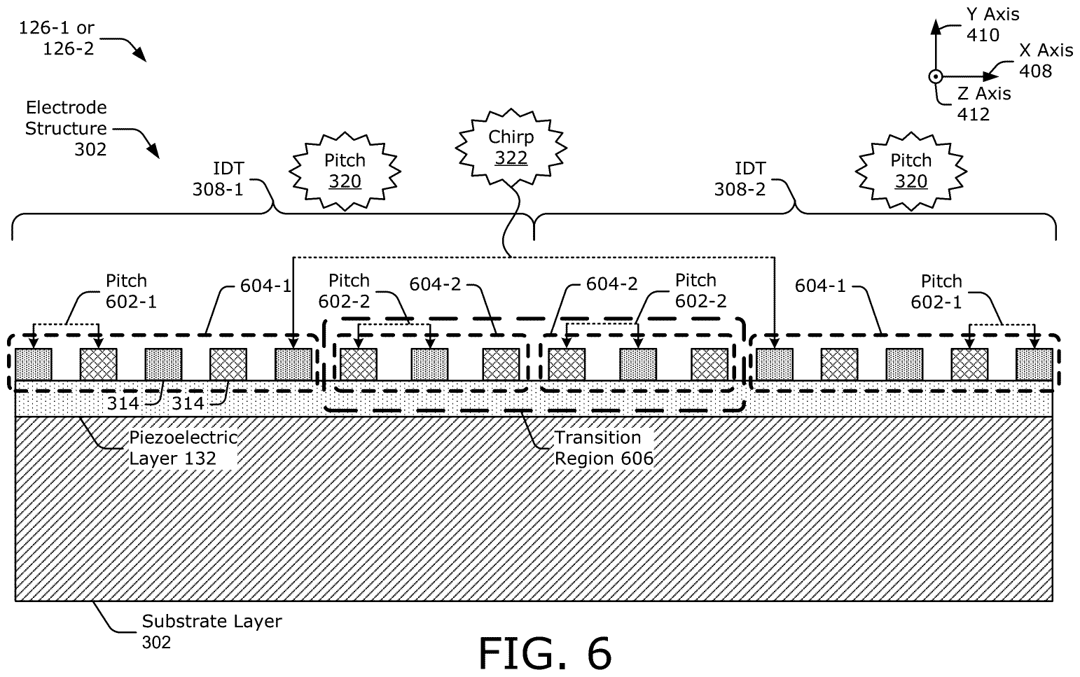

An example electrode structure 302 is further described with respect to FIGS. 4 to 6. The electrode structure 302 can be characterized by one or more geometric properties 318. Example geometric properties 318 include a pitch 320 and a chirp 322. The pitch 320 is further described with respect to FIG. 4. The chirp 322 is further described with respect to FIG. 6.

In example implementations, the piezoelectric layer 304 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), quartz, aluminium nitride (AlN), aluminium scandium nitride (AlScN), or some combination thereof. In general, the material that forms the piezoelectric layer 304 has a crystalline structure. This crystalline structure is defined by an ordered arrangement of particles (e.g., atoms, ions, or molecules).

The substrate layer 306 includes one or more sublayers that can support passivation, temperature compensation, power handling, mode suppression, and so forth. As an example, the substrate layer 306 can include at least one compensation layer 324, at least one charge-trapping layer 326, at least one support layer 328, or some combination thereof. These sublayers can be considered part of the substrate layer 306 or their own separate layers.

The compensation layer 324 can provide temperature compensation to enable the double-mode surface-acoustic-wave filter 126 to achieve a target temperature coefficient of frequency based on the thickness of the piezoelectric layer 304. In some implementations, a thickness of the compensation layer 324 can be tailored to provide mode suppression (e.g., suppress a spurious plate mode). In example implementations, the compensation layer 324 can be implemented using at least one silicon dioxide (SiO₂) layer, at least one doped silicon dioxide layer, at least one silicon nitride layer, at least one silicon oxynitride layer, or some combination thereof. In some applications, the substrate layer 306 may not include, for instance, the compensation layer 324 to reduce cost of the double-mode surface-acoustic-wave filter 126.

The charge-trapping layer 326 can trap induced charges at the interface between the compensation layer 324 and the support layer 328 in order to, for example, suppress nonlinear substrate effects. The charge-trapping layer 326 can include at least one polysilicon (poly-Si) layer (e.g., a polycrystalline silicon layer or a multicrystalline silicon layer), at least one amorphous silicon layer, at least one silicon nitride (SiN) layer, at least one silicon oxynitride (SiON) layer, at least one aluminium nitride (AlN) layer, diamond-like carbon (DLC), diamond, or some combination thereof.

The support layer 328 can enable the acoustic wave to form across the surface of the piezoelectric layer 304 and reduce the amount of energy that leaks into the substrate layer 306. In some implementations, the support layer 328 can also act as a compensation layer 324. In general, the support layer 328 is composed of material that is non-conducting and provides isolation. For example, the support layer 328 can be formed using silicon (Si) material (e.g., a doped high-resistive silicon material), sapphire material (e.g., aluminium oxide (Al₂O₃)), silicon carbide (SiC) material, fused silica material, quartz, glass, diamond, or some combination thereof. In some implementations, the support layer 328 has a relatively similar thermal expansion coefficient (TEC) as the piezoelectric layer 304. The support layer 328 can also have a particular crystal orientation to support the suppression or attenuation of spurious modes.

In some aspects, the double-mode surface-acoustic-wave filter 126 can be considered a resonator. Sometimes the double-mode surface-acoustic-wave filter 126 can be connected to other resonators associated with the same or different layer stacks than the double-mode surface-acoustic-wave filter 126. The electrode structure 302, the piezoelectric layer 304, and the substrate layer 306 are further described with respect to FIG. 4.

FIG. 4 illustrates an example implementation of the double-mode surface-acoustic-wave filter 126-1 or 126-2. A three-dimensional perspective view 400-1 of the double-mode surface-acoustic-wave filter 126 is shown at the top of FIG. 4, and a two-dimensional cross-section view 400-2 of the double-mode surface-acoustic-wave filter 126 is shown at the bottom of FIG. 4.

The double-mode surface-acoustic-wave filter 126 includes at least one electrode structure 302, at least one piezoelectric layer 304, and at least one substrate layer 306. In the depicted configuration shown in the two-dimensional cross-section view 400-2, the piezoelectric layer 304 is disposed between the electrode structure 302 and the substrate layer 306. A portion of the electrode structure 302 depicted in FIG. 4 includes at least a portion of one interdigital transducer 308. The electrode structure 302 can include additional interdigital transducers 308 not explicitly shown in FIG. 4. Also, the interdigital transducer 308 depicted in FIG. 4 can include additional fingers 314 not explicitly shown in FIG. 4.

In the three-dimensional perspective view 400-1, the interdigital transducer 308 is shown to have the two comb-shaped structures 310-1 and 310-2 with fingers 314 extending from two busbars 312 towards each other. The fingers 314 are arranged in an interlocking manner in between the two busbars 312 of the interdigital transducer 308 (e.g., arranged in an interdigitated manner). In other words, the fingers 314 connected to a first busbar 312 extend towards a second busbar 312 but do not connect to the second busbar 312. As such, there is a barrier region 402 (e.g., a transversal gap region) between the ends of these fingers and the second busbar 312. Likewise, fingers 314 connected to the second busbar 312 extend towards the first busbar 312 but do not connect to the first busbar 312. There is therefore a barrier region 402 between the ends of these fingers 314 and the first busbar 312.

In the direction along the busbars 312, there is an overlap region including a central region 404 where a portion of one finger 314 overlaps with a portion of an adjacent finger 314. This central region 404, including the overlap, may be referred to as the aperture, track, or active region where electric fields are produced between fingers 314 to cause an acoustic wave 406 to form at least in this region of the piezoelectric layer 304.

A physical periodicity of the fingers 314 is referred to as the pitch 320 of the interdigital transducer 308. The pitch 320 may be indicated in various ways. For example, in certain aspects, the pitch 320 may correspond to a magnitude of a distance between adjacent fingers 314 of the interdigital transducer 308 in the central region 404. This distance may be defined, for example, as the distance between center points of each of the fingers 314. The distance may be generally measured between a right (or left) edge of one finger 314 and the right (or left) edge of an adjacent finger 314 when the fingers 314 have uniform widths. In certain aspects, an average of distances between adjacent fingers 314 of the interdigital transducer 308 may be used for the pitch 320. The frequency at which the piezoelectric layer 304 vibrates is a main-resonance frequency of the electrode structure 302. The frequency is determined at least in part by the pitch 320 of the interdigital transducer 308 and other properties of the double-mode surface-acoustic-wave filter 126.

In the three-dimensional perspective view 400-1, the double-mode surface-acoustic-wave filter 126 is defined by a first (X) axis 408, a second (Y) axis 410, and a third (Z) axis 412. The first axis 408 and the second axis 410 are parallel to a planar surface of the piezoelectric layer 304, and the second axis 410 is perpendicular to the first axis 408. The third axis 412 is normal (e.g., perpendicular or orthogonal) to the planar surface of the piezoelectric layer 304. The busbars 312 of the interdigital transducer 308 are oriented to be parallel to the first axis 408. The fingers 314 of the interdigital transducer 308 are orientated to be parallel to the second axis 410. Also, an orientation of the piezoelectric layer 304 causes the acoustic wave 406 to mainly form in a direction of the first axis 408. As such, the acoustic wave 406 forms in a direction that is substantially perpendicular or orthogonal to the direction of the fingers 314 of the interdigital transducer 308.

One of ordinary skill in the art can appreciate the variety of filter stacks in which the double-mode surface-acoustic-wave filter 126 can be implemented. For example, some double-mode surface-acoustic-wave filters 126 can be implemented on a thin-film surface-acoustic-wave filter stack, as shown in FIG. 4. In general, the thin-film surface-acoustic-wave filter stack includes a piezoelectric layer with a thickness that is substantially less than a thickness of the substrate layer 306. As another example, other double-mode surface-acoustic-wave filters 126 can be implemented on a high-quality temperature-compensated filter stack. In this case, the piezoelectric layer 304 forms a substrate layer and the electrode structure 302 is disposed between a compensation layer 324 and the piezoelectric layer 304.

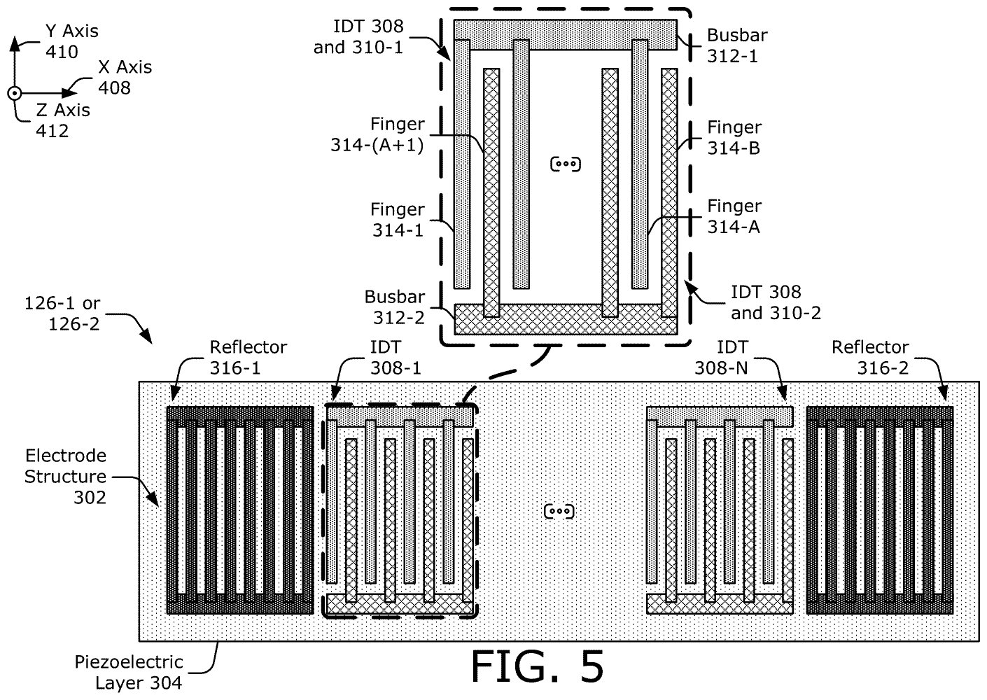

It should be appreciated that while a certain number of fingers are illustrated in FIG. 4, the number of actual fingers and lengths and width of the fingers and busbars may be different in an actual implementation. Such parameters depend on the particular application and desired filter characteristics. In addition, the double-mode surface-acoustic-wave filter 126 can include multiple interdigital transducers 308 to achieve a desired filter transfer function. An example electrode structure 302 with multiple interdigital transducers 308 is further described with respect to FIG. 5.

FIG. 5 illustrates an example electrode structure 302 of a double-mode surface-acoustic-wave filter 126-1 or 126-2. In the depicted configuration, the electrode structure 302 includes interdigital transducers 308-1 to 308-N, where N represents a positive integer. In example implementations, the variable N can be equal to 3, 4, 5, 7, and so forth.

The electrode structure 302 also includes reflectors 316-1 and 316-2. The interdigital transducers 308-1 to 308-N are arranged between the reflectors 316-1 and 316-2. In this way, the reflectors 316-1 and 316-2 reflect the acoustic wave 406 back towards the interdigital transducers 308-1 to 308-N. Each reflector 316-1 and 316-2 within the electrode structure 302 can have two busbars and a grating structure of conductive fingers that each connect to both busbars. In some implementations, a pitch of the reflector can be similar to or the same as the pitch 320 of the interdigital transducer 308 to reflect the acoustic wave 406 in the resonant frequency range.

Each interdigital transducer 308 includes a first busbar 312-1, a second busbar 312-2, and fingers 314-1 to 314-B, where B represents a positive integer. The first busbar 312-1 and the fingers 314-1 to 314-A form at least a portion of the first comb-shaped structure 310-1, where A represents a positive integer that is less than B. The fingers 314-1 to 314-A are connected to the first busbar 312-1 and extend along the second (Y) axis 410 towards the second busbar 312-2 without connecting to the second busbar 312-2. The second busbar 312-2 and the fingers 314-(A+1) to 314-B form at least a portion of the second comb-shaped structure 306-2. The fingers 314-(A+1) to 314-B are connected to the second busbar 312-2 and extend along the second (Y) axis 410 towards the first busbar 312-1 without connecting to the first busbar 312-1. The pitch 320 and chirp 322 of the electrode structure 302 are further described with respect to FIG. 6.

FIG. 6 illustrates example geometric properties 318 of the double-mode surface-acoustic-wave filter 126-1 or 126-2. Two adjacent interdigital transducers 308-1 and 308-2 of the electrode structure 302 are disposed on the piezoelectric layer 132. Each interdigital transducer 308 includes multiple fingers 314 and is associated with a pitch 320 and a chirp 322. The pitch 320 and/or chirp 322 can be similar or different between the two interdigital transducers 308-1 and 308-2 of the double-mode surface-acoustic-wave filter 126. In general, the pitch 320 represents an average distance between adjacent fingers 314 of the interdigital transducer 308.

In some implementations, individual pitches 602 between adjacent fingers 314 can vary across the interdigital transducer 308. For example, the interdigital transducers 308-1 and 308-2 each include a first set of fingers 604-1 associated with a first pitch 602-1 and a second set of fingers 604-2 associated with a second pitch 602-2. The second set of fingers 604-2 can be referred to as chirped fingers. The pitches 602-1 and 602-2 can be similar or different between different interdigital transducers 308. In general, the pitch 602-2 is greater than the pitch 602-1.

In some implementations, the first set of fingers 602-1 includes a larger quantity of fingers 314 than the second set of fingers 602-2. In example implementations, the second set of fingers 604-2 includes three or four fingers 314. The second set of fingers 604-2 are proximate to an outer edge of the interdigital transducer 308-1 (e.g., proximate to the adjacent interdigital transducer 308-2). The term “proximate” can refer to the second set of fingers 604-2 being closer to the outer edge of the interdigital transducer 308 compared to a center of the interdigital transducer 308. The first set of fingers 604-1 can include the remaining fingers 314 of the interdigital transducer 308. Some of the fingers 314 within the first set of fingers 604-1 can be proximate to a center of the interdigital transducer 308 (e.g., closer to a center of the interdigital transducer 308 compared to the outer edge).

Explained another way, the second set of fingers 604-2 are positioned within a transition region 606, which includes portions of two adjacent interdigital transducers 308 that form a smooth, continuous transition with quasi-periodic grating between adjacent elements. The transition region 606 can reduce bulk wave scattering losses. The first set of fingers 604-1 includes fingers 314 that are outside of the transition region 606. Although not explicitly shown, each interdigital transducer 308 can include a third set of fingers that are proximate to a second outer edge of the interdigital transducer 308 and are associated with another pitch 602, which may or may not be similar to the pitch 602-2.

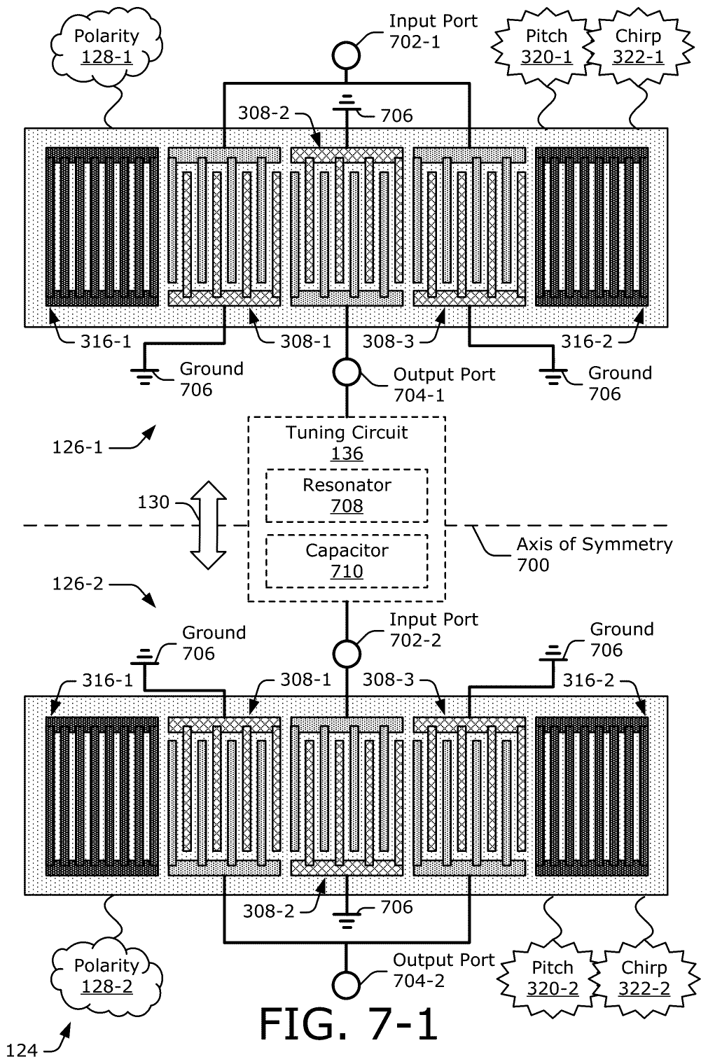

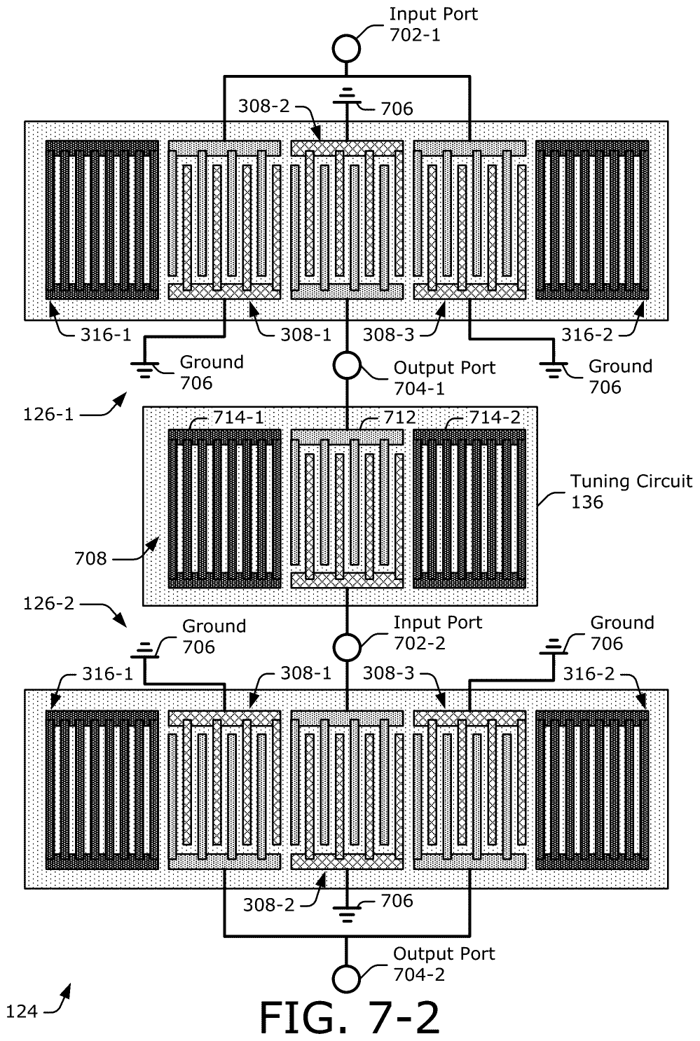

In general, the chirp 322 represents a length of the transition region 606 between adjacent interdigital transducers 308 across the first (X) axis 408. The length of the transition region 606 is based on a total quantity of fingers 314 within the second set of fingers 604-2 of the adjacent interdigital transducers 308 (e.g., the six fingers 314 shown in FIG. 6) and the associated pitch 604-2. In other words, the chirp 322 represents a distance between adjacent non-chirped fingers 314 within the first set of fingers 604-1 of the interdigital transducers 308-1 and 308-2. The chirp 322 can be similar or different between different adjacent interdigital transducers 308 within the electrode structure 302. The pitch 320 or the chirp 322 can vary between the two double-mode surface-acoustic-wave filters 126-1 and 126-2, as further described with respect to FIG. 7-1.

FIG. 7-1 illustrates example twin double-mode surface-acoustic-wave filters 124 with opposite polarities 128 and at least one geometric offset 130. In the depicted configuration, the twin double-mode surface-acoustic-wave filters 124 include the first double-mode surface-acoustic-wave filter 126-1 and the second double-mode surface-acoustic-wave filter 126-2. The first double-mode surface-acoustic-wave filter 126-1 and the second double-mode surface-acoustic-wave filter 126-2 have approximately the same physical structure or physical architecture. The term “approximately” can take account slight size differences caused by process variations, which can be on the order of tens of nanometers. In general, the double-mode surface-acoustic-wave filters 126-1 and 126-2 have similar quantities of components, as further described below.

In some aspects, the first double-mode surface-acoustic-wave filter 126-1 and the second double-mode surface-acoustic-wave filter 126-2 have a same quantity of fingers 314, a same quantity of interdigital transducers 308 (e.g., three interdigital transducers 308-1 to 308-3), a same quantity of reflectors 316 (e.g., two reflectors 316-1 to 316-2), approximately a same busbar length, and/or approximately a same aperture length.

In this example, the twin double-mode surface-acoustic-wave filters 124 are shown to be approximately symmetrical to each other across an axis of symmetry 700. The axis of symmetry 700 is parallel to the first (X) axis 408. The term “approximately” can account for slight differences caused by process variations. Generally, the symmetrical aspect of the twin double-mode surface-acoustic-wave filters 124 refers to the twin double-mode surface-acoustic-wave filters 124 having a same physical structure, as explained above. This symmetry also facilitates implementing the twin double-mode surface-acoustic-wave filters 124 with opposite polarities 128, as described below. Aspects of the symmetry may or may not apply to a layout or positioning of the twin double-mode surface-acoustic-wave filters 124. Also, aspects of the symmetry do not necessarily apply to the acoustical aspects of the twin double-mode surface-acoustic-wave filters 124 due to the geometric offset 130.

In FIG. 4, the twin double-mode surface-acoustic-wave filters 124 are shown to be reflections of each other across the axis of symmetry 700. However, components of the first double-mode surface-acoustic-wave filter 126-1 do not necessarily have to be aligned with corresponding components of the second double-mode surface-acoustic-wave filter 126-2 along the second (Y) axis 410. In some implementations, for instance, the second double-mode surface-acoustic-wave filter 126-2 can be offset along the first (X) axis 410 relative to the first double-mode surface-acoustic-wave filter 126-1. In this case, the twin double-mode surface-acoustic-wave filters 124 have symmetrical physical structures relative to the axis of symmetry 700, but the overall layout is not symmetrical across the axis of symmetry 700.

The first double-mode surface-acoustic-wave filter 126-1 includes an input port 702-1 and an output port 704-1. In this example, the first double-mode surface-acoustic-wave filter 126-1 includes at least three interdigital transducers 308 (e.g., interdigital transducers 308-1 to 308-3). At least two of the interdigital transducers 308 (e.g., interdigital transducers 308-1 and 308-3) have first busbars 312-1 coupled to the input port 702-1 and second busbars coupled to a ground 706. At least one of the interdigital transducers 308 (e.g., interdigital transducer 308-2) has a first busbar 312-1 coupled to the output port 704-1 and a second busbar 312-2 coupled to the ground 706. In this case, the interdigital transducer 308-2 that is coupled to the output port 704-1 is positioned between the other interdigital transducers 308-1 and 308-3, which are coupled to the input port 702-1. In this configuration, the first double-mode surface-acoustic-wave filter 126-1 has a first polarity 128-1.

The second double-mode surface-acoustic-wave filter 126-2 includes an input port 702-2 and an output port 704-2. The input port 702-2 of the second double-mode surface-acoustic-wave filter 126-2 is coupled to the output port 704-1 of the first double-mode surface-acoustic-wave filter 126-1. In this example, the second double-mode surface-acoustic-wave filter 126-2 includes at least three interdigital transducers 308 (e.g., interdigital transducers 308-1 to 308-3). At least one of the interdigital transducers 308 (e.g., interdigital transducer 308-2) has a first busbar 312-1 coupled to the input port 702-2 and a second busbar coupled to the ground 706. At least two of the interdigital transducers 308 (e.g., interdigital transducers 308-1 and 308-3) have first busbars 312-1 coupled to the output port 704-2 and second busbars 312-2 coupled to the ground 706. In this case, the interdigital transducer 308-2 that is coupled to the input port 702-2 is positioned between the other interdigital transducers 308-1 and 308-3, which are coupled to the output port 704-2. In this configuration, the second double-mode surface-acoustic-wave filter 126-2 has a second polarity 128-2, which is opposite the first polarity 128-1.

The physical structures of the first double-mode surface-acoustic-wave filter 126-1 and the second double-mode surface-acoustic-wave filter 126-2 are related by at least one geometric offset 130. Consider a case in which the electrode structure 302 of the first double-mode surface-acoustic-wave filter 126-1 has at least one first pitch 320-1 and at least one first chirp 322-1. Also, the electrode structure 302 of the second double-mode surface-acoustic-wave filter 126-2 has at least one second pitch 320-2 and at least one second chirp 322-2.

In some cases, the pitches 320-1 and 320-2 of the first and second double-mode surface-acoustic-wave filters 126-1 and 126-2 are related together by the pitch offset 132. The pitch offset 132 represents an absolute value of a difference between the pitches 320-1 and 320-2. Example pitch offsets 132 can be between approximately 0.2% and 0.8% of the first pitch 320-1. In an example implementation, the pitch offset 132 is approximately equal to 0.2%, 0.4%, 0.6%, or 0.8% of the first pitch 320-1. In general, the term “approximately” can mean that the pitch offset 132 can be within +/−10% of a specified value or less (e.g., within +/−5%, +/−3%, or +/−2% of the specified value).

Additionally or alternatively, the chirps 322-1 and 322-2 of the first and second double-mode surface-acoustic-wave filters 126-1 and 126-2 are related together by the chirp offset 134. The chirp offset 134 represents an absolute value of a difference between the chirps 322-1 and 322-2. Example chirp offsets 134 can be between approximately 2% and 8% of the first chirp 322-1. In an example implementation, the pitch offset 132 is approximately equal to 2%, 4%, 6%, or 8% of the first pitch 320-1. In general, the term “approximately” can mean that the chirp offset 134 can be within +/−10% of a specified value or less (e.g., within +/−5%, +/−3%, or +/−2% of the specified value).

Sometimes the twin double-mode surface-acoustic-wave filters 124 are related together by both the pitch offset 132 and the chirp offset 134. In an example implementation, the pitch offset 132 is approximately equal to 0.4%, and the chirp offset is approximately equal to 4%. In one example, the twin double-mode surface-acoustic-wave filters 124 has a passband associated with frequencies that are less than one gigahertz (although implementations associated with higher passbands are contemplated). In some aspects, the twin double-mode surface-acoustic-wave filters 124 are jointly designed to attenuate frequencies associated with long-term evolution uplink bands 20 and/or 28. In this example, an overall dimension of the first double-mode surface-acoustic-wave filter 126-1 and the second double-mode surface-acoustic-wave filter 126-2 is smaller than 1×1 millimeter. For example, the overall dimension is approximately equal to 0.7×0.6 millimeters. In general, the term “approximately” can mean that the dimensions can be within +/−10% of a specified value or less (e.g., within +/−5%, +/−3%, or +/−2% of the specified value).

Some implementations of can optionally include the tuning circuit 136, as shown in FIG. 7-1. The tuning circuit 136 can be coupled between the first double-mode surface-acoustic-wave filter 126-1 and the second double-mode surface-acoustic-wave filter 126-2. In particular, the tuning circuit 136 can be coupled between the output port 704-1 of the first double-mode surface-acoustic-wave filter 126-1 and the input port 702-2 of the second double-mode surface-acoustic-wave filter 126-2. In example implementations, the tuning circuit 136 can include at least one resonator 708 (e.g., at least one acoustic resonator) and/or at least one capacitor 710 (e.g., a shunt capacitor). Sometimes the tuning circuit 136 is implemented with both the resonator 708 and the capacitor 710.

The resonator 708 can include a surface-acoustic-wave filter, as further described with respect to FYG. 7-2. The resonator 708 is coupled in series between the first and second double-mode surface-acoustic-wave filters 126-1 and 126-2. In general, the resonator 708 can provide additional out-of-band frequency suppression for frequencies that are higher than the passband (e.g., on a “right” side of the passband).

In some implementations, the capacitor 710 is implemented by an interdigital transducer structure. In this way, the capacitor 710 can be integrated within the double-mode surface-acoustic-wave filters 126-1 and/or 126-2 or implemented within a separate interdigital transducer. In one example, the capacitor 710 is implemented as a separate interdigital transducer with fingers oriented perpendicular to fingers 314 of the double-mode surface-acoustic-wave filters 126-1 and 126-2.

For some applications, the tuning circuit 136 can be implemented with the capacitor 710 and does not include the resonator 708. The capacitor 710 can provide additional out-of-band frequency suppression for frequencies that are lower than the passband (e.g., on a “left” side of the passband). In an example implementation that does not include the resonator 708, the capacitor 710 can have a capacitance on the order of a few picofarads, such as approximately 2 or 3 picofarads. By using the capacitor 710 and not including the resonator 708, the tuning circuit 136 can have a smaller footprint compared to other tuning circuits 136 that include the resonator 708. An example implementation of the tuning circuit 136 is further described with respect to FIG. 7-2.

FIG. 7-2 illustrates an example tuning circuit 136 coupled between the twin double-mode surface-acoustic-wave filters 124. In the depicted configuration, the tuning circuit 136 includes the resonator 708. The resonator 708 is implemented as a surface-acoustic-wave filter, which includes an electrode structure with at least one interdigital transducer 712. The interdigital transducer 712 of the resonator 708 can be similar or different to an interdigital transducer 308 of the double-mode surface-acoustic-wave filters 126-1 or 126-2. The electrode structure of the resonator 708 can optionally include reflectors, such as reflectors 714-1 and 714-2 shown in FIG. 7-2.

One busbar of the interdigital transducer 712 is coupled to the output port 704-1 of the first double-mode surface-acoustic-wave filter 126-1. Another busbar of the interdigital transducer 712 is coupled to the input port 702-2 of the second double-mode surface-acoustic-wave filter 126-2. In this manner, the resonator 708 is coupled in series between the twin double-mode surface-acoustic-wave filters 124.

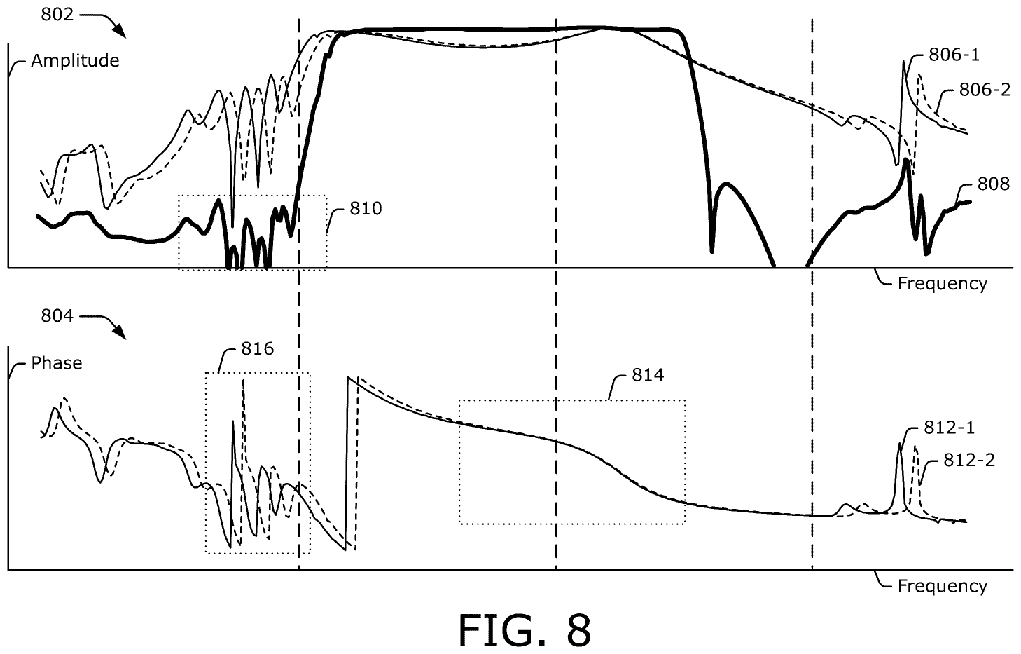

The symmetry and opposite polarity 128 of the twin double-mode surface-acoustic-wave filters 124 cause phases of the twin double-mode surface-acoustic-wave filters 124 to be similar within a passband and approximately 180 degrees out-of-phase outside at least a portion of the passband, as further described with respect to FIG. 8.

FIG. 8 illustrates example frequency responses of the double-mode surface-acoustic-wave filters 126-1 and 126-2. A first graph 802 depicts amplitude responses 806-1 and 806-2 of the double-mode surface-acoustic-wave filters 126-1 and 126-2, respectively. A composite amplitude response 808 of the twin double-mode surface-acoustic-wave filters 124 is also shown in the first graph 802. As shown at 810, the composite amplitude response 808 can attenuate out-of-band frequencies by 15 decibels (dB) or more (e.g., by approximately 15, 20, 30, 40 or 45 dB). In general, the term “approximately” can mean that the attenuation can be within +1-10% of a specified value or less (e.g., within +/−5%, +/−3%, or +/−2% of the specified value).

A second graph 804 depicts phase responses 812-1 and 812-2 of the double-mode surface-acoustic-wave filters 126-1 and 126-2, respectively. At 814, a difference in the phases of the double-mode surface-acoustic-wave filters 126-1 and 126-2 is approximately zero degrees. At 816, a difference in the phases of the double-mode surface-acoustic-wave filters 126-1 and 126-2 is approximately 180 degrees. In general, the term “approximately” can mean that the difference in phases can be within +1-10% of a specified value or less (e.g., within +/−5%, +/−3%, or +/−2% of the specified value). The attenuation in the amplitude response 808 and opposite phases of the phase responses 812-1 and 812-2 observed outside of the passband are due, at least in part, to the geometric offset 130 (e.g., the pitch offset 132 and/or the chirp offset 134) of the twin double-mode surface-acoustic-wave filters 124.

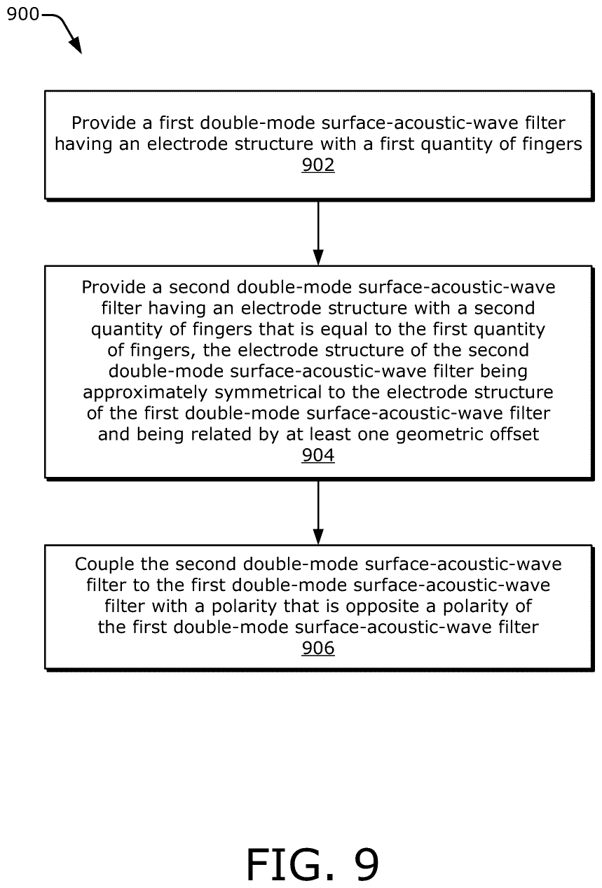

FIG. 9 is a flow diagram illustrating an example process 900 for manufacturing twin double-mode surface-acoustic-wave filters with opposite polarities and a geometric offset. The process 900 is described in the form of a set of blocks 902-906 that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the process 900, or an alternative process. Operations represented by the illustrated blocks of the process 900 may be performed to manufacture twin double-mode surface-acoustic-wave filters 124 (e.g., of FIG. 1 or 2). More specifically, the operations of the process 900 may be performed, at least in part, to manufacture two double-mode surface-acoustic-wave filters 126-1 and 126-2 with opposite polarities 128 and at least one geometric offset 130 (e.g., of FIGS. 5 to 7-1).

At 902, a first double-mode surface-acoustic-wave filters is provided having an electrode structure with a first quantity of fingers. For example, a manufacturing process provides or forms the first double-mode surface-acoustic-wave filter 126-1 (or a first double-mode surface-acoustic-wave structure), which includes an electrode structure 302 with a first quantity of fingers, as shown in FIG. 5.

At 904, a second double-mode surface-acoustic-wave filter having an electrode structure with a second quantity of fingers that is equal to the first quantity of fingers is provided. The electrode structure of the second double-mode surface-acoustic-wave filter is approximately symmetrical to the electrode structure of the first double-mode surface-acoustic-wave filter and is related by at least one geometric offset. For example, the manufacturing process provides or forms the second double-mode surface-acoustic-wave filter 126-2 (or a second double-mode surface-acoustic-wave structure), which includes an electrode structure 302 with a second quantity of fingers that is equal to the first quantity of fingers. The electrode structures 302 of the first and second double-mode surface-acoustic-wave filters 126-1 and 126-2 are approximately symmetrical and are related by at least one geometric offset 130, as shown in FIG. 7-1.

Example geometric offsets 130 include a pitch offset 132 and a chirp offset 134. The pitch offset 132 is a difference between a pitch 320 of the first double-mode surface-acoustic-wave filter 126-1 and a pitch 320 of the second double-mode surface-acoustic-wave filter 126-2. In some aspects, the pitch 320 represents an average distance between adjacent fingers within an interdigital transducer 308 of the electrode structure 302. The chirp offset 134 is a difference between a chirp 322 of the first double-mode surface-acoustic-wave filter 126-1 and a chirp 322 of the second double-mode surface-acoustic-wave filter 126-2. In some aspects, the chirp 322 represents a length of the transition region 606 between adjacent interdigital transducers 308 across the first (X) axis 408, as shown in FIG. 6. In other words, the chirp 322 represents a shortest distance between adjacent non-chirped fingers 314 the interdigital transducers 308-1 and 308-2.

At 906, the second double-mode surface-acoustic-wave filter is coupled to the first double-mode surface-acoustic-wave filter with a polarity that is opposite a polarity of the first double-mode surface-acoustic-wave filter. For example, the second double-mode surface-acoustic-wave filter 126-2 is coupled to the first double-mode surface-acoustic-wave filter 126-1 with a polarity 128-2 that is opposite a polarity 128-1 of the first double-mode surface-acoustic-wave filter 126-1, as shown in FIG. 7-1.

In some implementations of the double-mode surface-acoustic-wave filter 126-1 or 126-2, the pitch 320 is similar across the interdigital transducers 308 and/or the chirp 322 is similar between adjacent interdigital transducers 308 (e.g., across multiple transition regions 606). In other implementations of the double-mode surface-acoustic-wave filter 126-1 or 126-2, the pitch 320 varies between the interdigital transducers 308 and/or the chirp 322 varies between different adjacent interdigital transducers 308 (e.g., across different transition regions 606). In this case, the geometric offset 130 can relate corresponding pitches 320 and/or corresponding chirps 322 of the double-mode surface-acoustic-wave filter 126-1 and 126-2 together.

For example, a first pitch offset 132 can relate a pitch 320 of the interdigital transducer 308-1 of the first double-mode surface-acoustic-wave filter 126-1 to a pitch 320 of the interdigital transducer 308-1 of the second double-mode surface-acoustic-wave filter. Also, a second pitch offset 132 can relate a pitch 320 of the interdigital transducer 308-2 of the first double-mode surface-acoustic-wave filter 126-1 to a pitch 320 of the interdigital transducer 308-2 of the second double-mode surface-acoustic-wave filter. Additionally, a third pitch offset 132 can relate a pitch 320 of the interdigital transducer 308-3 of the first double-mode surface-acoustic-wave filter 126-1 to a pitch 320 of the interdigital transducer 308-3 of the second double-mode surface-acoustic-wave filter.

As another example, a first chirp offset 134 can relate a chirp 322 associated with adjacent transducers 308-1 and 308-2 of the first double-mode surface-acoustic-wave filter 126-1 to a chirp 322 associated with adjacent transducers 308-1 and 308-2 of the second double-mode surface-acoustic-wave filter 126-2. Also, a second chirp offset 134 can relate a chirp 322 associated with adjacent transducers 308-2 and 308-3 of the first double-mode surface-acoustic-wave filter 126-1 to a chirp 322 associated with adjacent transducers 308-2 and 308-3 of the second double-mode surface-acoustic-wave filter 126-2.

Some aspects are described below.

Aspect 1: An apparatus comprising:
a first double-mode surface-acoustic-wave structure comprising an electrode structure having:
   a first quantity of fingers; and
   a first pitch,
the first double-mode surface-acoustic-wave structure having a first polarity; and
a second double-mode surface-acoustic-wave structure coupled to the first double-mode surface-acoustic-wave structure with a second polarity that is opposite the first polarity, the second double-mode surface-acoustic-wave structure comprising an electrode structure having:
   a second quantity of fingers that is equal to the first quantity of fingers; and
   a second pitch that differs from the first pitch by a pitch offset.

Aspect 2: The apparatus of aspect 1, wherein a physical structure of the first double-mode surface-acoustic-wave structure is approximately the same as a physical structure of the second double-mode surface-acoustic-wave structure.

Aspect 3: The apparatus of aspect 2, wherein an aperture length of the first double-mode surface-acoustic-wave structure and an aperture length of the second double-mode surface-acoustic-wave structure are approximately equal.

Aspect 4: The apparatus of any previous aspect, wherein the first pitch and the second pitch each represent an average distance between adjacent fingers of the electrode structure.

Aspect 5: The apparatus of any previous aspect, wherein an absolute value of the pitch offset is between approximately 0.2% and 0.8% of the first pitch.

Aspect 6: The apparatus of aspect 5, wherein the absolute value of the pitch offset is approximately equal to 0.4% of the first pitch.

Aspect 7: The apparatus any previous aspect, wherein:
the electrode structure of the first double-mode surface-acoustic-wave structure has a first chirp; and
the electrode structure of the second double-mode surface-acoustic-wave structure has a second chirp that differs from the first chirp by a chirp offset.

Aspect 8: The apparatus of aspect 7, wherein an absolute value of the chirp offset is between approximately 2% and 8% of the first chirp.

Aspect 9: The apparatus of any previous aspect, wherein a physical structure of the first double-mode surface-acoustic-wave structure and a physical structure of the second double-mode surface-acoustic-wave structure are approximately symmetrical.

Aspect 10: The apparatus of aspect 9, wherein:
the first double-mode surface-acoustic-wave structure comprises:
   an input port; and
   an output port;
the electrode structure of the first double-mode surface-acoustic-wave structure comprises at least three interdigital transducers, at least two interdigital transducers of the at least three interdigital transducers have first busbars coupled to the input port of the first double-mode surface-acoustic-wave structure and second busbars coupled to ground, at least one interdigital transducer of the at least three interdigital transducers has a first busbar coupled to the output port of the first double-mode surface-acoustic-wave structure and a second busbar coupled to the ground, the at least one interdigital transducer positioned between the at least two interdigital transducers;
the second double-mode surface-acoustic-wave structure comprises:
   an input port coupled to the output port of the first double-mode surface-acoustic-wave structure; and
   an output port; and
the electrode structure of the second double-mode surface-acoustic-wave structure comprises at least three interdigital transducers, at least one interdigital transducers of the at least three interdigital transducers has a first busbar coupled to the input port of the second double-mode surface-acoustic-wave structure and a second busbar coupled to the ground, at least two interdigital transducers of the at least three interdigital transducers have first busbars coupled to the output port of the second double-mode surface-acoustic-wave structure and second busbars coupled to the ground, the at least one interdigital transducer positioned between the at least two interdigital transducers.

Aspect 11: The apparatus of any previous aspect, further comprising:
a tuning circuit coupled between the first double-mode surface-acoustic-wave structure and the second double-mode surface-acoustic-wave structure.

Aspect 12: The apparatus of aspect 11, wherein the tuning circuit comprises at least one of the following:
an acoustic resonator coupled in series between the first double-mode surface-acoustic-wave structure and the second double-mode surface-acoustic-wave structure; or
a shunt capacitor.

Aspect 13: The apparatus of any previous aspect, further comprising:
a wireless transceiver coupled to at least one antenna, the wireless transceiver comprising a filter comprising the first double-mode surface-acoustic-wave structure and the second double-mode surface-acoustic-wave structure and configured to filter, using the first double-mode surface-acoustic-wave structure and the second double-mode surface-acoustic-wave structure, a wireless signal communicated via the at least one antenna.

Aspect 14: An apparatus comprising:
a first double-mode surface-acoustic-wave structure comprising an electrode structure having:
   a first quantity of fingers; and
   a first chirp,
the first double-mode surface-acoustic-wave structure having a first polarity; and
a second double-mode surface-acoustic-wave structure coupled to the first double-mode surface-acoustic-wave structure with a second polarity that is opposite the first polarity, the second double-mode surface-acoustic-wave structure comprising an electrode structure having:
   a second quantity of fingers that is equal to the first quantity of fingers; and
   a second chirp that differs from the first chirp by a chirp offset.

Aspect 15: The apparatus of aspect 14, wherein the first chirp and the second chirp each represent a length of a transition region between adjacent interdigital transducers of the electrode structure.

Aspect 16: The apparatus of aspect 14 or 15, wherein an absolute value of the chirp offset is between approximately 2% and 8% of the first chirp.

Aspect 17: The apparatus of aspect 16, wherein the absolute value of the chirp offset is approximately 4% of the first chirp.

Aspect 18: The apparatus of any one of aspects 14-17, wherein:
the electrode structure of the first double-mode surface-acoustic-wave structure has a first pitch; and
the electrode structure of the second double-mode surface-acoustic-wave structure has a second pitch that differs from the first pitch by a pitch offset.

Aspect 19: The apparatus of aspect 18, wherein an absolute value of the pitch offset is between approximately 0.2% and 0.8% of the first pitch.

Aspect 20: The apparatus of any one of aspects 14-19, wherein a physical structure of the first double-mode surface-acoustic-wave structure and a physical structure of the second double-mode surface-acoustic-wave structure are approximately symmetrical.

Aspect 21: A method of manufacturing, the method comprising:
providing a first double-mode surface-acoustic-wave filter having an electrode structure with a first quantity of fingers;
providing a second double-mode surface-acoustic-wave filter having an electrode structure with a second quantity of fingers that is equal to the first quantity of fingers, the electrode structure of the second double-mode surface-acoustic-wave filter being approximately symmetrical to the electrode structure of the first double-mode surface-acoustic-wave filter and being related by at least one geometric offset; and
coupling the second double-mode surface-acoustic-wave filter to the first double-mode surface-acoustic-wave filter with a polarity that is opposite a polarity of the first double-mode surface-acoustic-wave filter.

Aspect 22: The method of aspect 21, wherein the at least one geometric offset comprises at least one of the following:
a pitch offset; or
a chirp offset.

Aspect 23: The method of aspect 22, wherein:
the at least one geometric offset comprises the pitch offset and the chirp offset;
the pitch offset is approximately equal to 0.4% of a pitch of the first double-mode surface-acoustic-wave filter; and
the chirp offset is approximately equal to 4% of a chirp of the first double-mode surface-acoustic-wave filter.

Aspect 24: An apparatus comprising:
two double-mode surface-acoustic-wave structures coupled together with opposite polarities, the two double-mode surface-acoustic-wave structures having physical structures that are approximately symmetrical to each other and are related by at least one geometric offset.

Aspect 25: The apparatus of aspect 24, wherein:
the at least one geometric offset comprises a pitch offset; and
an absolute value of the pitch offset is between approximately 0.2% and 0.8% of a pitch of a double-mode surface-acoustic-wave structure of the two double-mode surface-acoustic-wave structures.

Aspect 26: The apparatus of aspect 24 or 25, wherein:
the at least one geometric offset comprises a chirp offset; and
an absolute value of the chirp offset is between approximately 2% and 8% of a chirp of a double-mode surface-acoustic-wave structure of the two double-mode surface-acoustic-wave structures.

Aspect 27: The apparatus of any one of aspects 24-26, wherein:
the at least one geometric offset comprises a pitch offset and a chirp offset;
an absolute value of the pitch offset is approximately equal to 0.4% of a pitch of a double-mode surface-acoustic-wave structure of the two double-mode surface-acoustic-wave structures; and
an absolute value of the chirp offset is approximately equal to 4% of a chirp of the double-mode surface-acoustic-wave structure.

Aspect 28: The apparatus of aspect 27, wherein:
the two double-mode surface-acoustic-wave structures each comprise seven interdigital transducers and two reflectors;
an overall dimension of the two double-mode surface-acoustic-wave structures is smaller than one by one millimeter; and
the two double-mode surface-acoustic-wave structures are jointly configured to have a passband associated with frequencies that are less than one gigahertz.

Aspect 29: The apparatus of any one of aspects 24-28, further comprising:
a tuning circuit coupled between the two double-mode surface-acoustic-wave structures, the tuning circuit comprising at least one of the following:
   an acoustic resonator coupled in series between the two double-mode surface-acoustic-wave structures; or
   a shunt capacitor.

Aspect 30: The apparatus of any one of aspects 24-29, wherein the two double-mode surface-acoustic-wave structures comprise longitudinal-coupled double-mode surface-acoustic-wave structures.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a first double-mode surface-acoustic-wave structure comprising an electrode structure having:
a first quantity of fingers; and
a first pitch,
the first double-mode surface-acoustic-wave structure having a first polarity; and
a second double-mode surface-acoustic-wave structure coupled to the first double-mode surface-acoustic-wave structure with a second polarity that is opposite the first polarity, the second double-mode surface-acoustic-wave structure comprising an electrode structure having:
a second quantity of fingers that is equal to the first quantity of fingers; and
a second pitch that differs from the first pitch by a pitch offset.

2. The apparatus of claim 1, wherein a physical structure of the first double-mode surface-acoustic-wave structure is approximately the same as a physical structure of the second double-mode surface-acoustic-wave structure.

3. The apparatus of claim 2, wherein an aperture length of the first double-mode surface-acoustic-wave structure and an aperture length of the second double-mode surface-acoustic-wave structure are approximately equal.

4. The apparatus of claim 1, wherein the first pitch and the second pitch each represent an average distance between adjacent fingers of the electrode structure.

5. The apparatus of claim 1, wherein an absolute value of the pitch offset is between approximately 0.2% and 0.8% of the first pitch.

6. The apparatus of claim 5, wherein the absolute value of the pitch offset is approximately equal to 0.4% of the first pitch.

7. The apparatus of claim 1, wherein:
the electrode structure of the first double-mode surface-acoustic-wave structure has a first chirp; and
the electrode structure of the second double-mode surface-acoustic-wave structure has a second chirp that differs from the first chirp by a chirp offset.

8. The apparatus of claim 7, wherein an absolute value of the chirp offset is between approximately 2% and 8% of the first chirp.

9. The apparatus of claim 1, wherein a physical structure of the first double-mode surface-acoustic-wave structure and a physical structure of the second double-mode surface-acoustic-wave structure are approximately symmetrical.

10. The apparatus of claim 9, wherein:
the first double-mode surface-acoustic-wave structure comprises:
an input port; and
an output port;
the electrode structure of the first double-mode surface-acoustic-wave structure comprises at least three interdigital transducers, at least two interdigital transducers of the at least three interdigital transducers have first busbars coupled to the input port of the first double-mode surface-acoustic-wave structure and second busbars coupled to ground, at least one interdigital transducer of the at least three interdigital transducers has a first busbar coupled to the output port of the first double-mode surface-acoustic-wave structure and a second busbar coupled to the ground, the at least one interdigital transducer positioned between the at least two interdigital transducers;
the second double-mode surface-acoustic-wave structure comprises:
an input port coupled to the output port of the first double-mode surface-acoustic-wave structure; and
an output port; and
the electrode structure of the second double-mode surface-acoustic-wave structure comprises at least three interdigital transducers, at least one interdigital transducers of the at least three interdigital transducers has a first busbar coupled to the input port of the second double-mode surface-acoustic-wave structure and a second busbar coupled to the ground, at least two interdigital transducers of the at least three interdigital transducers have first busbars coupled to the output port of the second double-mode surface-acoustic-wave structure and second busbars coupled to the ground, the at least one interdigital transducer positioned between the at least two interdigital transducers.

11. The apparatus of claim 1, further comprising:
a tuning circuit coupled between the first double-mode surface-acoustic-wave structure and the second double-mode surface-acoustic-wave structure.

12. The apparatus of claim 11, wherein the tuning circuit comprises at least one of the following:
an acoustic resonator coupled in series between the first double-mode surface-acoustic-wave structure and the second double-mode surface-acoustic-wave structure; or
a shunt capacitor.

13. The apparatus of claim 1, further comprising:
a wireless transceiver coupled to at least one antenna, the wireless transceiver comprising a filter comprising the first double-mode surface-acoustic-wave structure and the second double-mode surface-acoustic-wave structure and configured to filter, using the first double-mode surface-acoustic-wave structure and the second double-mode surface-acoustic-wave structure, a wireless signal communicated via the at least one antenna.

14. An apparatus comprising:
a first double-mode surface-acoustic-wave structure comprising an electrode structure having:
a first quantity of fingers; and
a first chirp,
the first double-mode surface-acoustic-wave structure having a first polarity; and
a second double-mode surface-acoustic-wave structure coupled to the first double-mode surface-acoustic-wave structure with a second polarity that is opposite the first polarity, the second double-mode surface-acoustic-wave structure comprising an electrode structure having:
a second quantity of fingers that is equal to the first quantity of fingers; and
a second chirp that differs from the first chirp by a chirp offset.

15. The apparatus of claim 14, wherein the first chirp and the second chirp each represent a length of a transition region between adjacent interdigital transducers of the electrode structure.

16. The apparatus of claim 14, wherein an absolute value of the chirp offset is between approximately 2% and 8% of the first chirp.

17. The apparatus of claim 16, wherein the absolute value of the chirp offset is approximately 4% of the first chirp.

18. The apparatus of claim 14, wherein:
the electrode structure of the first double-mode surface-acoustic-wave structure has a first pitch; and
the electrode structure of the second double-mode surface-acoustic-wave structure has a second pitch that differs from the first pitch by a pitch offset.

19. The apparatus of claim 18, wherein an absolute value of the pitch offset is between approximately 0.2% and 0.8% of the first pitch.

20. The apparatus of claim 14, wherein a physical structure of the first double-mode surface-acoustic-wave structure and a physical structure of the second double-mode surface-acoustic-wave structure are approximately symmetrical.

21. A method of manufacturing, the method comprising:
providing a first double-mode surface-acoustic-wave filter having an electrode structure with a first quantity of fingers;
providing a second double-mode surface-acoustic-wave filter having an electrode structure with a second quantity of fingers that is equal to the first quantity of fingers, the electrode structure of the second double-mode surface-acoustic-wave filter being approximately symmetrical to the electrode structure of the first double-mode surface-acoustic-wave filter and being related by at least one geometric offset; and
coupling the second double-mode surface-acoustic-wave filter to the first double-mode surface-acoustic-wave filter with a polarity that is opposite a polarity of the first double-mode surface-acoustic-wave filter.

22. The method of claim 21, wherein the at least one geometric offset comprises at least one of the following:
a pitch offset; or
a chirp offset.

23. The method of claim 22, wherein:
the at least one geometric offset comprises the pitch offset and the chirp offset;
the pitch offset is approximately equal to 0.4% of a pitch of the first double-mode surface-acoustic-wave filter; and
the chirp offset is approximately equal to 4% of a chirp of the first double-mode surface-acoustic-wave filter.

24. An apparatus comprising:
two double-mode surface-acoustic-wave structures coupled together with opposite polarities, the two double-mode surface-acoustic-wave structures having physical structures that are approximately symmetrical to each other and are related by at least one geometric offset.

25. The apparatus of claim 24, wherein:
the at least one geometric offset comprises a pitch offset; and
an absolute value of the pitch offset is between approximately 0.2% and 0.8% of a pitch of a double-mode surface-acoustic-wave structure of the two double-mode surface-acoustic-wave structures.

26. The apparatus of claim 24, wherein:
the at least one geometric offset comprises a chirp offset; and
an absolute value of the chirp offset is between approximately 2% and 8% of a chirp of a double-mode surface-acoustic-wave structure of the two double-mode surface-acoustic-wave structures.

27. The apparatus of claim 24, wherein:
the at least one geometric offset comprises a pitch offset and a chirp offset;
an absolute value of the pitch offset is approximately equal to 0.4% of a pitch of a double-mode surface-acoustic-wave structure of the two double-mode surface-acoustic-wave structures; and
an absolute value of the chirp offset is approximately equal to 4% of a chirp of the double-mode surface-acoustic-wave structure.

28. The apparatus of claim 27, wherein:
the two double-mode surface-acoustic-wave structures each comprise seven interdigital transducers and two reflectors;
an overall dimension of the two double-mode surface-acoustic-wave structures is smaller than one by one millimeter; and
the two double-mode surface-acoustic-wave structures are jointly configured to have a passband associated with frequencies that are less than one gigahertz.

29. The apparatus of claim 24, further comprising:
a tuning circuit coupled between the two double-mode surface-acoustic-wave structures, the tuning circuit comprising at least one of the following:
an acoustic resonator coupled in series between the two double-mode surface-acoustic-wave structures; or
a shunt capacitor.

30. The apparatus of claim 24, wherein the two double-mode surface-acoustic-wave structures comprise longitudinal-coupled double-mode surface-acoustic-wave structures.
